(19) United States
(12) Patent Application Publication
(10) Pub. No.: US 2012/0038039 A1
(43) Pub. Date: Feb. 16, 2012

(54) SEMICONDUCTOR DEVICE AND METHOD FOR MANUFACTURING SEMICONDUCTOR DEVICE

(75) Inventors: Kiyofumi Sakaguchi, Mobara-shi (JP); Takao Yonehara, Atsugi-shi (JP)

(73) Assignee: CANON KABUSHIKI KAISHA, Tokyo (JP)

(21) Appl. No.: 13/262,912

(22) PCT Filed: Mar. 29, 2010
(86) PCT No.: PCT/JP2010/002242

§ 371 Date: Oct. 4, 2011

(30) Foreign Application Priority Data
Apr. 6, 2009 (JP) 2009-092315
Apr. 6, 2009 (JP) 2009-092316

(51) Int. Cl. H01L 23/48; H01L 21/30; H01L 21/78

(52) U.S. Cl. 257/734; 438/458; 438/455; 257/E23.01; 257/E21.599

(57) ABSTRACT

A conventional transfer technique has low efficiency in separation at a separation layer and costs much.

The present invention is characterized in that a plurality of second integrated circuits of smaller chip size than that of a first integrated circuit provided on a first substrate are formed in a semiconductor layer formed on a separation layer provided on a second semiconductor substrate, at least the semiconductor layer is separated for each second integrated circuit so that the end surfaces of the separation layer are inclined or curved, the first semiconductor substrate is bonded to the second semiconductor substrate, and a bonded structure is separated along the separation layer.

### TECHNICAL FIELD

The present invention relates to a semiconductor device used for semiconductor memory such as DRAM (Dynamic Random-Access Memory), flash memory, and the like, and logical IC such as CPU (Central Processing Unit), DSP (Digital Signal Processor), and the like, and a method for manufacturing a semiconductor device. In particular, the present invention relates to a method for manufacturing a so-called three-dimensionally mounted semiconductor device in which a plurality of chips each having an integrated circuit (IC) formed therein are stacked and packaged.

### BACKGROUND ART

A method for manufacturing three-dimensionally mounted IC by transferring, to a handle substrate, a semiconductor layer having a CMOS circuit formed therein is described in Proceeding of International Electron Device Meeting, Washington D.C., USA, December 2005, Hiroyuki Sanda et al. “Fabrication and Characterization of CMOSFETs on Porous Silicon for Novel Device Layer Transfer”. An example of such a method includes forming a separation layer composed of porous silicon on a surface of a silicon wafer, epitaxially growing a semiconductor layer composed of single crystal silicon on the separation layer, and forming a CMOS circuit in the semi-conductor layer.

Then, the semiconductor layer having the CMOS circuit formed therein is bonded to a handle substrate and separated at the separation layer to transfer the semiconductor layer to the handle substrate. This process is repeated a plurality of times to stack a plurality of semiconductor layers each having the CMOS circuit formed therein on the handle substrate.

U.S. Pat. No. 6,638,835 discloses a process in which a semiconductor layer having a transistor formed therein is bonded, through a polymer film, to a handle substrate having a backside recess formed therein, transferring the semiconductor layer to the handle substrate. Then, this process is repeated to form stacked transistors.

### CITATION LIST

### Patent Literature

PTL 1: U.S. Pat. No. 6,638,835

### SUMMARY OF INVENTION

However, the conventional transfer technique has low efficiency in separation at a separation layer and thus costs much. In particular, in the technical field of a method for manufacturing a semiconductor device having a structure in which integrated circuit chips of small chip size or functional elements are stacked on an integrated circuit chip of large chip size, it is important to improve the transfer technique.

The present invention has been achieved in consideration of the background art and provides a semiconductor device which is three-dimensionally mounted at low cost by an improved transfer technique.

### Solution to Problem

The gist of the present invention lies in a method for manufacturing a semiconductor device, the method including the steps of forming a plurality of first integrated circuits on the surface side of a first semiconductor substrate; forming a plurality of second integrated circuits in a semiconductor layer which is formed on a separation layer provided on a second semiconductor substrate, the chip size of the second integrated circuits being smaller than that of the first integrated circuits; separating at least the semiconductor layer for each second integrated circuit so that the end surfaces of the separation layer are inclined or curved surfaces; bonding the first semiconductor substrate and the second semiconductor substrate so that bonding pads formed on the surface sides of the first integrated circuits are bonded to bonding pads formed on the surface sides of the second integrated circuits to form bonded structures; separating the bonded structures along the separation layer to obtain the first semiconductor substrate to which the semiconductor layer having the second integrated circuits formed therein is transferred; and dicing the first semiconductor substrate to which the plurality of second integrated circuits are transferred to obtain stacked chips each including the first integrated circuit and the second integrated circuit.

The other gist of the present invention lies in a method for manufacturing a semiconductor device, the method including the steps of preparing a semiconductor substrate having a semiconductor layer formed on a separation layer; separating at least the semiconductor layer for each region so that the end surfaces of the separation layer are inclined or curved surfaces; bonding a plurality of the separated semiconductor layers to a support substrate to form a bonded structure; and removing at least a portion of the separation layer exposed in the inclined or curved surfaces and separating the bonded structure along the separation layer to form a support substrate to which the semiconductor layer is transferred.

According to the present invention, in a bonded structure in which a plurality of semiconductor layers, a plurality of separation layers, and at least one semiconductor substrate are bonded to a common semiconductor substrate or support substrate, separation can be efficiently performed successively or simultaneously at the respective separation layers. As a result, a three-dimensionally mounted semiconductor device can be manufactured at low cost.

### BRIEF DESCRIPTION OF DRAWINGS

FIG. 1 is a schematic sectional view illustrating an example of a dicing method used in the present invention.

FIG. 2A is a schematic sectional view illustrating a method for manufacturing a semiconductor device according to a first embodiment.

FIG. 2B is a schematic sectional view illustrating a method for manufacturing a semiconductor device according to a first embodiment.

FIG. 2C is a schematic sectional view illustrating a method for manufacturing a semiconductor device according to a first embodiment.

FIG. 2D is a schematic sectional view illustrating a method for manufacturing a semiconductor device according to a first embodiment.

FIG. 2E is a schematic sectional view illustrating a method for manufacturing a semiconductor device according to a first embodiment.

FIG. 3A is a schematic sectional view illustrating a method for manufacturing a semiconductor device according to a second embodiment.

FIG. 3B is a schematic sectional view illustrating a method for manufacturing a semiconductor device according to a second embodiment.

FIG. 4 is a schematic view illustrating a separating method used in the present invention.

FIG. 5 is a schematic sectional view of a stacked chip.

FIG. 6 is a schematic sectional view illustrating a method for manufacturing a semiconductor device according to a fifth embodiment.

FIG. 7A is a schematic sectional view illustrating a method for manufacturing a semiconductor device according to a seventh embodiment.

FIG. 7B is a schematic sectional view illustrating a method for manufacturing a semiconductor device according to a seventh embodiment.

FIG. 8A is a schematic sectional view illustrating a method for manufacturing a semiconductor device according to an eighth embodiment.

FIG. 8B is a schematic sectional view illustrating a method for manufacturing a semiconductor device according to an eighth embodiment.

FIG. 8C is a schematic sectional view illustrating a method for manufacturing a semiconductor device according to an eighth embodiment.

FIG. 8D is a schematic sectional view illustrating a method for manufacturing a semiconductor device according to an eighth embodiment.

FIG. 8E is a schematic sectional view illustrating a method for manufacturing a semiconductor device according to an eighth embodiment.

FIG. 9 is a schematic sectional view of a stacked chip.

### DESCRIPTION OF EMBODIMENTS

### First Embodiment

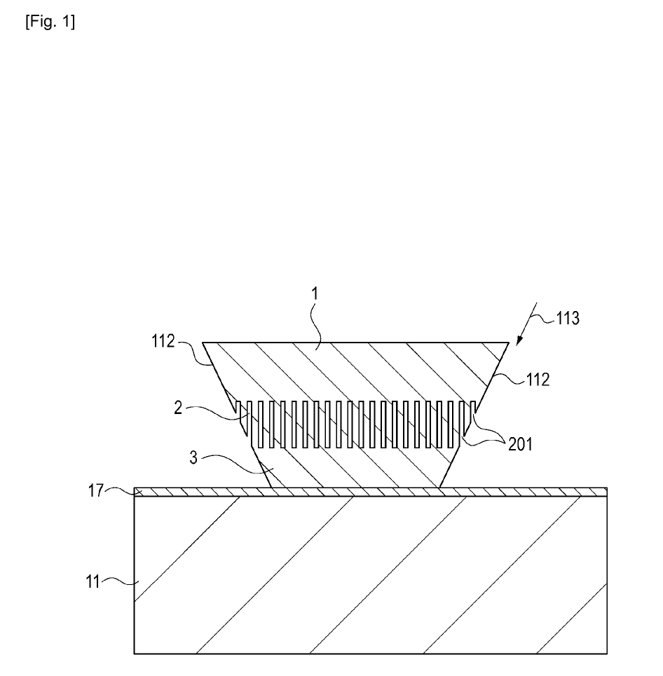

First, a dicing method used in a method for manufacturing a semiconductor device according to the present invention and an example of a subsequent bonding step are described with reference to FIG. 1.

A substrate 11 is one to which a semiconductor layer 3 is subsequently and temporarily or permanently transferred and may include a silicon wafer, glass, a resin film, a metal film, or the like. A first semiconductor substrate is prepared as the substrate 11, and first integrated circuits 17 are formed on the surface side of the semiconductor substrate 11 by a known semiconductor manufacturing process. In this case, functional elements such as transistors are formed, an insulating layer is formed and etched, and then a wiring pattern is formed by deposition and CMP of a metal layer for wiring. Then, bonding pads for achieving electric connection with the outside are formed on the uppermost surface. As a result, the first integrated circuits 17 are formed.

On the other hand, a separation layer 2 and a semiconductor layer 3 to be transferred (moved) are formed on a surface of a second semiconductor substrate 1, the semi-conductor layer 3 being formed on the separation layer 2. As the semiconductor layer 3, a single crystal semiconductor can be used, and like in the first semiconductor substrate, second integrated circuits and bonding pads are formed in the semiconductor layer 3 according to demand.

The second semiconductor substrate 1 having the semiconductor layer 3 in which a plurality of second integrated circuits are formed is diced so that at least one of the sides (end surfaces) of a die is inclined. Specifically, a dicing blade is placed at an angle of about 45 degrees to 80 degrees with respect to the surface of the substrate to be cut, and the semiconductor substrate 1 is cut by grinding (refer to arrow 113 in FIG. 1). The inclination may decrease or increase toward the bonding side or dicing may be performed at the same inclination angle (the same direction). When dicing is performed at the same inclination angle, the structure diced has a parallelogram sectional shape, not a trapezoidal sectional shape, thereby minimizing an useless area. Then, an integrated circuit chip having an inclined end surface (diced end surface) 112 is bonded to the surface of the semiconductor substrate 11 so that the semiconductor layer 3 faces inward to obtain a bonded structure. In this case, according to demand, the surface side of the semiconductor layer 3 can be bonded to the surface side of the substrate 11 through an adhesive.

Then, in order to separate the bonded structure at the separation layer 2 shown in FIG. 1, a force is applied to the semiconductor substrate 1 in a direction in which a separation function occurs. Consequently, cracks occur in the separation layer 2, and the semiconductor substrate 1 is separated leaving the semiconductor layer 3 having the integrated circuits formed therein on the semiconductor substrate 11 side, thereby producing stacked semiconductor chips.

When a layer composed of a porous material such as silicon or the like is used as the separation layer 2, pores formed by anodization have openings 201 in the inclined surfaces, and thus an etching solution penetrates into the porous material to progress selective etching. Therefore, the porous material constituting the separation layer 2 is partially removed to form recesses in the inclined end surfaces 112 of the chips. Thus, when a pressurized fluid is applied, cracks occur in the porous layer along the porous layer due to the wedge function of the fluid to separate the semiconductor substrate 1 from the semiconductor layer 3. In this case, it is effective to use a chip supporting plate by bonding a panel for preventing scattering of the chips or by pressing a panel having a recess corresponding to the chip shape. A mesh-like chip supporting plate can be used for avoiding inhibition of a water flow.

In addition, when the separation layer includes a plurality of porous layers having different pore densities, separation occurs at the boundaries between the different pore densities by applying a pressurized fluid. The porous layers having different porosities remain on the back of the separated semiconductor chip and the surface of the substrate, and the remaining porous layers serve as protecting layers so that progress and propagation of cracks in elements and circuits can be inhibited during separation with the fluid.

The porous material such as silicon can be formed by anodization in which a current is passed through the entire wafer surface in a chemical conversion solution in a direction perpendicular to the surface. In the anodization, a P⁺-type or N⁺-type substrate can be used or a substrate can be doped with P-type or N-type impurities so that at least an anodization region is P⁺-type or N⁺-type. In the present invention, in particular, a P⁺-type substrate can be used or a substrate can be doped with P-type impurities so that at least an anodization region is P⁺-type. In addition, conductivity is increased by controlling the P⁺-type or N⁺-type region resistivity, and, according to demand, the porous layer is partially left so that when a chip is formed, the porous layer can function as a shield for noise such as electromagnetic waves and the like. The pores are continued from the surface to the end, and the formation direction coincides with the current-carrying direction. That is, the pores of the porous layer grow in a direction perpendicular to the wafer surface, significant enhancement of the etching rate is observed in the growth direction of pores. The inventors found that when a HF solution is used, the increased etching rate reaches several hundreds of thousands of times that of crystal silicon without pores.

However, pore walls are present in the direction perpendicular to the pores, i.e., the direction to the wafer end surfaces, and etching little proceeds because the pore walls are composed of crystal silicon. Namely, the significant anisotropy of the etching rate plays a very important role when the end surfaces of the separation layer are inclined to expose the ends of some of the pores of the porous layer in the inclined surfaces. In order to introduce a fluid to boundaries between a plurality of porous layers, it was found to be most effective to form introduction spaces for applying trigger while avoiding separation at an interface bonded to the adhesive layer. Therefore, selective etching of the porous layer with inclined surface is effective in forming spaces for initially introducing the fluid.

Alternatively, the substrate 1 may be separated from the semiconductor layer 3 by selectively etching the porous separation layer in the inclined surfaces 112 in the transverse direction without using the fluid. However, this method requires a long time and exhibits low selectivity and deterioration of anisotropy, and thus etching of the substrate composed of the same crystal silicon and a device active layer proceeds isotropically. Therefore, the pressurized fluid is used.

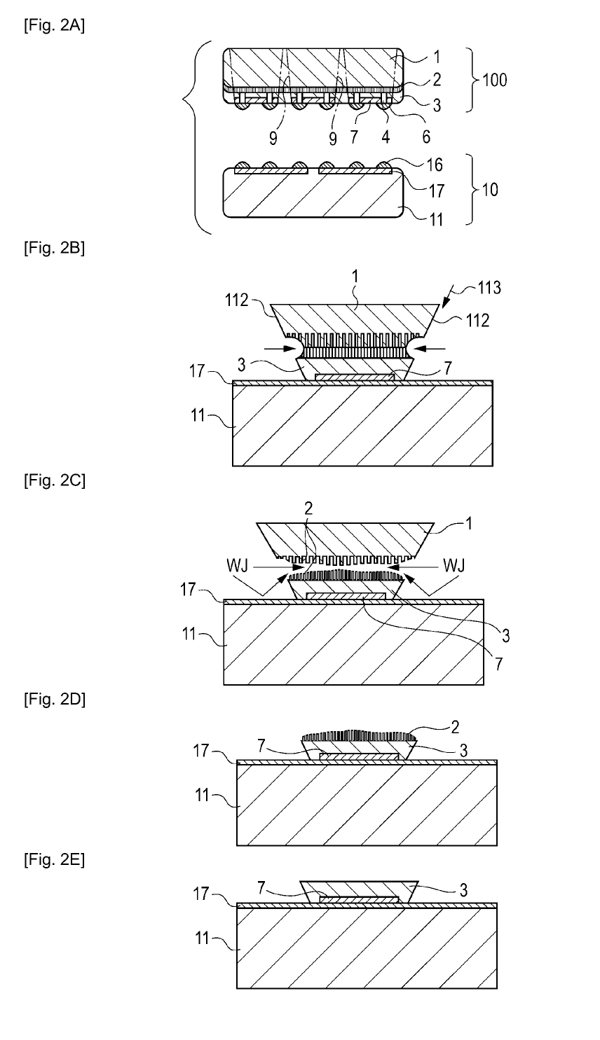

A method for manufacturing a semiconductor device according to the present invention is described in detail below with reference to FIGS. 2A to 2E.

As the first semiconductor substrate 11, a semiconductor substrate such as a bulk silicon wafer, an epitaxial silicon wafer, or the like is prepared. Then, a plurality of first integrated circuits 17 is formed on the surface side of the semiconductor substrate 11 by a known manufacturing process. Here, the first integrated circuits are integrated circuit portions which subsequently function as chips (dies). For example, the first integrated circuits are logical IC such as CPU, DSP, or the like. In addition, bonding pads 16 composed of solder, gold, copper, or the like are formed. As a result, a structure denoted by reference numeral 10 in FIG. 2A is obtained.

On the other hand, at least two separation layers 2 of porous silicon or the like, which have different porosities, are formed on a second semiconductor substrate 1 such as a bulk silicon wafer, and a plurality of second integrated circuits 7, e.g., at least three second integrated circuits 7, are formed on the separation layers 2 to prepare a wafer as a second semiconductor substrate. Here, the second integrated circuits may be semiconductor memories such as DRAM, flash memories, or the like. In case of semiconductor memory, a second integrated circuit includes many memory cells, a selection circuit for selecting one of the memory cells, a signal processing circuit for reading and writing signals from and in the memory cells, and the like.

In addition, active elements such as MOS transistors and multilayer wiring for connecting many MOS transistors are formed, and then through holes (including grooves) referred to as “though holes” or “via holes” are formed in a semiconductor layer. Then, insulating films are formed on the inner wall surfaces of the through holes to form insulating inner wall surfaces, and the through holes are filled with a conductor to form through electrodes 4 (through silicon via technique). In this step, the etching time is controlled so that the depth Dt of the through holes is smaller than the thickness t3 of the semiconductor layer 3. Namely, the through holes are formed to be such shallow holes that Dt<t3, i.e., the bottoms of the conductive layers in the through holes do not reach the separation layer 2. The thickness t3 of the semiconductor layer 3 can be selected from a range of 1.0 micrometer to 20 micrometers, more preferably a range of 1.0 micrometer to 10 micrometers. For example, when a CMOS circuit is formed, the thickness t3 of the semiconductor layer 3 is 1.0 micrometer to 2.0 micrometers, while when a memory structure is formed, the thickness t3 of the semiconductor layer 3 is 1.0 micrometer to 10.0 micrometers depending on the capacity which stores various memory charges. The depth Dt of the through holes is a half or more of the thickness of the semiconductor layer 3 so that a remaining portion having a thickness of one twentieth or less of the thickness of the semiconductor layer 3 remains at the bottom of a groove. Namely, the through holes are designed to satisfy Expression (1). The conductor may be composed of any one of tin (Sn), nickel (Ni), copper (Cu), gold (Au), and aluminum (Al) or an alloy of at least one of these metals. In FIG. 2B and the subsequent drawings, the through wiring may be omitted for simplification.

### [Math. 1]

t3/2≦Dt<t3−(t3/20) (1)

Then, bonding pads 6 composed of sold, gold, or copper are formed. In the drawing, for the sake of easy understanding, the through electrodes and the bonding pads are shown inside an integrated circuit chip. However, generally, a plurality of through electrodes and bonding pads are provided in the peripheral portion of an integrated circuit chip. In the present invention, the through electrodes are connected to wiring of the integrated circuit of each chip and have the function to achieve electric connection with wiring when chips are stacked. Specifically, a power supply line, an input/output line, a clock signal line, and a ground line can be formed.

Then, dicing is carried out using a dicing saw from the surface side of the semiconductor layer 3. Consequently, grooves 9 are formed between the adjacent integrated circuits 7 to independently separate between the second integrated circuits. At this time, dicing is carried out with a dicing blade which is inclined from the surface side of the semiconductor layer 3 to the surface of the semiconductor substrate. Dicing with the dicing blade at different angles produces a structure denoted by reference numeral 100 in FIG. 2A. As a result, a plurality of dies each corresponding to the chip size of the second integrated circuits and having the inclined end surfaces 112 can be formed. The dies can be formed by dicing the second semiconductor substrate so that the chip size decreases toward the bonded surface side. In addition, the end surfaces of the separation layer 2 may be curved surfaces.

The diced second semiconductor substrate 1 is placed on the surface of the first semiconductor substrate 11 so that the surfaces having the bonding pads formed thereon face each other, the bonding pads are formed on a plurality of first integrated circuits 17 on the first semiconductor circuit 11.

The diced semiconductor substrate 1 and the semiconductor substrate 11 are bonded together with an adhesive 18 provided therebetween. In this step, the bonding pads on both semiconductor substrates are also bonded to be electrically short-circuited in the manner of flip chip bonding.

When an adhesive is used, the peripheries of the first and second substrates subjected to flip chip bonding are covered with a sealing member such as an acrylic resin using a dispenser or the like, the sealing member is cured after an opening is provided therein, and an adhesive having lower viscosity is introduced into the inner space through the opening and then cured. This technique of filling an adhesive is the same as a known method for filling a liquid crystal material used in a method for manufacturing liquid crystal panels. As the adhesive which can be used in the present invention, an adhesive which satisfies low viscosity, low impurities, high weather resistance, low outgassing, low shrinkability, heat resistance at 160 degrees Celsius, high adhesive force, low thermal expansion coefficient, high thermal conductivity, and high volume resistivity can se selected. Examples of the adhesive satisfying these conditions include acrylic, methacrylic (acrylate), epoxy (acid anhydride curing agent), polyimide, and polyimideamide (polyimide=nylon modified) adhesives. The adhesive is applied to the bonded surface (substrate or chip surface), dried leaving predetermined tackiness, and then heat-treated at a predetermined temperature with a predetermined load applied. Instead of or in addition to the adhesive, bonding can be performed using a film (hot-melt sheet) functioning an adhesive. In the present invention, for example, die bonding film FH series, DF series, or HS series, or under fill film UF series, or the like, which is manufactured by Hitachi Chemical Co., Ltd., can be used.

Alternatively, adhesive particles (bonding beads) may be dispersed in a region where the bonding pads are not provided in the surface of one of the semiconductor substrates, and the bonding beads may be cured by deformation at the same time as flip chip bonding of the other semiconductor substrate. The adhesive interposed by the method is used for enhancing the adhesive strength of the two semiconductor substrates in addition to the adhesive force of the bonding pads when the semiconductor layer 3 is subsequently separated at the separation layer 2.

In addition, as a material functioning as both a bonding adhesive and conduction, an anisotropic conductive film or paste may be used for electrically short-circuiting in the thickness direction and insulating between the adjacent bonding pads in the transverse direction.

Next, similarly, the semiconductor substrate 1 in which the integrated circuit is formed and separated is bonded to the adjacent first integrated circuit 17.

FIG. 2B shows a portion of the bonded structure when one integrated circuit 17 and the semiconductor layer 3 having one integrated circuit 7 formed therein are bonded and then immersed in an etching solution.

As shown in FIG. 2B, the exposed portions of the separation layer are partially removed from the side surfaces of the structured formed by bonding the two semiconductor substrates 1 and 11, specifically the inclined side surfaces (dicing end surfaces) of a die including the first semiconductor substrate, the separation layer, and the semiconductor layer.

Then, as shown by arrows WJ in FIG. 2C, a high-pressure stream not containing abrasive grains (ultrasonic waves or laser beams are not necessarily applied) is sprayed. Then, the semiconductor layer 3 is separated from the second semiconductor substrate 1 at the separation layer 2. As a result, as shown in FIG. 2D, the semiconductor substrate 1 is removed, and the semiconductor layer 3 having the integrated circuit 7 formed therein is transferred to the first semiconductor substrate 11 from the second semiconductor substrate 1.

The separation method is not limited to the above-described so-called water jet method and may be a gas jet method of spraying high-pressure gas such as nitrogen or the like. In other words, a fluid having a freely deformable wedge function may be sprayed. As shown in the drawing, the end surfaces of the die are inclined, and thus when a porous silicon material is used as the separation layer, etching selectively proceeds because many openings are present in the exposed side surfaces of the separation layer. A recess is formed between a chip including the second semiconductor substrate and the first semiconductor substrate. Therefore, when a wedge is inserted into the recess to apply force vector in a direction in which the two semiconductor substrates are separated from each other, the both substrates are separated along an interface between porous silicon layers having different porosities due to the release of inherent strain energy which is concentrated in the porous silicon layer interface.

After separation, the separation layer 2 remains on the semiconductor layer side of the first semiconductor substrate 11 or on the second semiconductor substrate side or the porous silicon layers with different porosities remain on the respective substrate sides. In particular, when a laminate of at least two porous layers having different porosities is used as the separation layer, separation occurs near the interface between the porous layers along the interface, and the separation layer functions as a protecting layer for inhibiting propagation of cracks to the surface of the remaining separated product.

Consequently, the remaining porous layer has a uniform thickness over the entire surface region of the semiconductor substrate having the integrated circuit formed thereon.

Examples of the etching solution include a mixed solution containing hydrogen fluoride and hydrogen peroxide and a mixed solution containing hydrogen fluoride, ammonium fluoride, and hydrogen peroxide. A method of separating only by etching without using the wedge function of the fluid can be used. In this case, the separation layer composed of a porous material may little remain on the exposed surface of the transferred semiconductor layer 3 as shown in FIG. 2D.

When the separating layer 2 remains, according to demand, the remaining separation layer is removed by etching with the mixed solution or the like to expose the back side of the semiconductor layer. Then, the back side of the semiconductor layer is etched until the through electrodes are exposed, and bonding pads are formed using solder, gold, or the like after the through electrodes are exposed.

As a result, as shown in FIG. 2E, a stacked chip having the integrated circuits 7 and 17 of two different sizes, large and small, is produced. Although not shown in the drawing, the same structure is also formed in an adjacent region on the semiconductor substrate 11. When the number of the integrated circuits stacked is two, dicing is performed by forming grooves in the regions between the adjacent integrated circuits and cutting the bonded structures with a dicing saw disposed vertically, thereby separating the integrated circuits into independent chips. As a result, a stacked chip having at least the first integrated circuit 7 of small size and the second integrated circuit 17 of large size, i.e., a three-dimensionally mounted semiconductor device, can be produced.

### Second Embodiment

In this embodiment, all end surfaces of a die are not inclined, but at least one end surface is inclined, and an exposed portion of a separation layer exposed in the inclined surface is partially removed. Then, separation is performed by spraying a fluid.

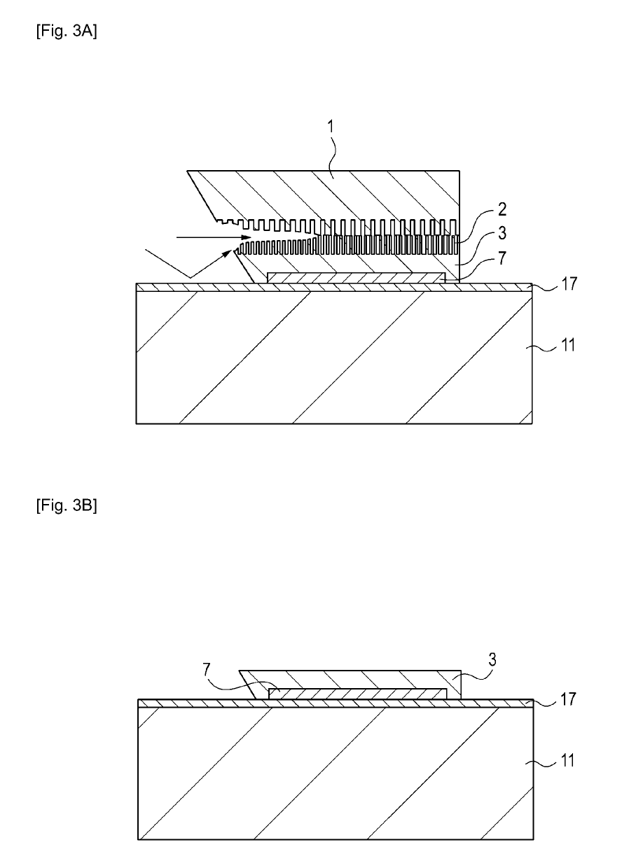

FIG. 3A is a schematic section for explaining the separation method, and FIG. 3B is a schematic sectional view of stacked semiconductor chips after separation.

### Third Embodiment

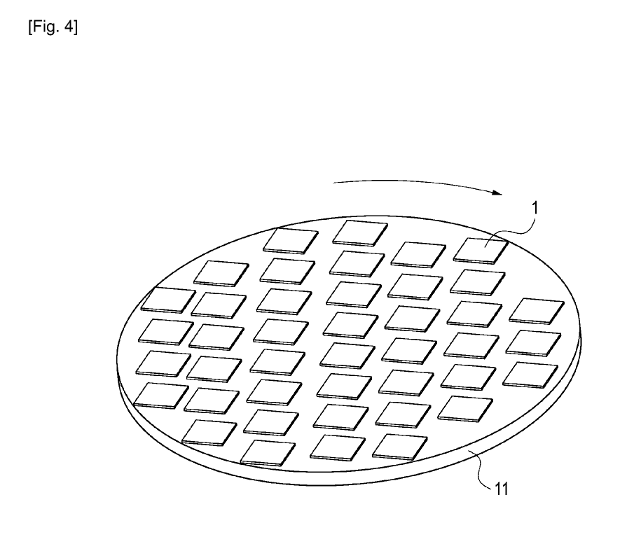

First, a plurality of structures which are the same as shown in FIG. 2B in the above-described first embodiment are prepared on a common semiconductor substrate 11. This state is shown in FIG. 4.

A pressurized fluid is sprayed to the inclined surfaces of chips from a fluid spray nozzle (spray opening) while the semiconductor substrate 11 is rotated. In this case, the fluid is sprayed to the inclined surface of each of the chips while the fluid ejection opening and the bonded structures are relatively moved so that diced semiconductor substrates 1 are successively separated from the semiconductor substrate 11 by the wedge function of the fluid. As a result, a plurality of semiconductor layers (semiconductor chips 7) are transferred and left with a space therebetween on the semiconductor substrate 11.

Further, the bonded structures shown in FIG. 4 are cut to be separated into integrated circuit chips by dicing including forming grooves in the regions between the adjacent integrated circuits with a dicing saw. Then, the diced multilayer chip is die-bonded to a mounting substrate composed of a metal, ceramic, an insulating sheet having metal wiring, or the like, and then packaged.

Although any one of the drawings is enlarged in the longitudinal direction, in fact, the chip size (the lateral length in the drawings) is significantly larger than the thickness (the length in the longitudinal direction).

In the above-described embodiments, the integrated circuits 7 and 17 formed on the first semiconductor substrate 11 and each semiconductor layer 3 may be the same or different circuits. The integrated circuits 17 may be circuits on a relatively large circuit scale. As the integrated circuits 7, semiconductor memory requiring a storage operation, such as DRAM and the like, and nonvolatile semiconductor memory referred to as “flash memory”, such as EEPROM, MRAM, and the like, can be used. The number of the layers stacked is not limited to 2 as shown in the drawing, and the number may be 8 or more, particularly 12 or more. On the other hand, as the integrated circuits 17, the above-described logical IC on the larger circuit scale than the integrated circuits 7 or 27 can be used. Further, the semiconductor substrate 11 may include a thin layer.

### Fourth Embodiment

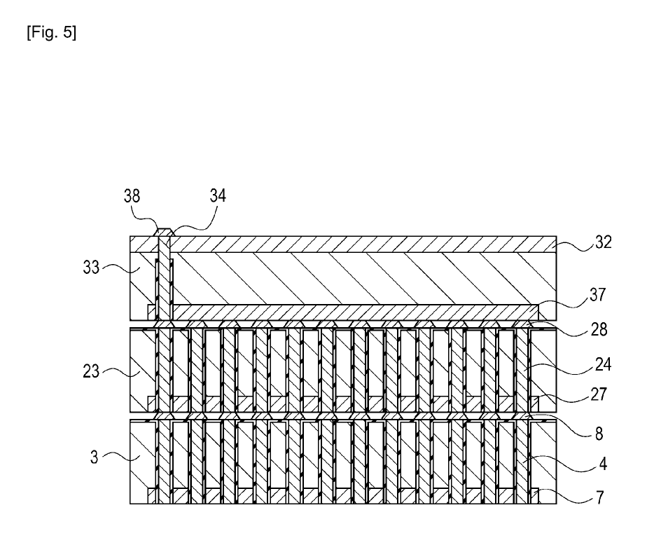

In this embodiment, a stacked chip obtained by the method for manufacturing a semiconductor device according to the present invention are described. FIG. 5 shows a cross-section of a portion in which three integrated circuits of small chip size are stacked. FIG. 5 does not show an integrated circuit chip of large chip size provided below the three integrated circuits. The stacked chip of this embodiment includes the integrated circuit chip of large chip size and the structure stacked thereon as shown in FIG. 5.

In a semiconductor layer 3 in which an integrated circuit 7 of small chip size, such as semiconductor memory or the like, through electrodes 4 and solder bumps 8 serving as bonding pads are formed. Further, a semiconductor layer 23 in which an integrated circuit 27 composed of the same semiconductor memory is formed is stacked on the semiconductor layer 3, through electrodes 24 and solder bumps 28 serving as bonding pads being formed in the semiconductor layer 23.

Further, a semiconductor layer 33 in which an integrated circuit 37 composed of the same semiconductor memory is formed is stacked on the semiconductor layer 23. In addition, a separation layer 32 is not removed and remains on the top semiconductor layer 33.

A through electrode 34 is disposed to be stacked on the lower through electrodes 24 and 4 and short-circuited to provide conduction therebetween. In each of the semiconductor layers 3, 23, and 33, insulating films are formed on the inner walls of through holes, and thus each of the semiconductor layers is not short-circuited with the insides of the through holes. On the other hand, the remaining separation layer 32 composed of a porous material is a low-resistance layer composed of silicon containing a high concentration of boron, and thus the separation layer 32 is short-circuited with the through electrode 34 so that the low-resistance layer 32 used as the separation layer composed of a porous material can be used as an electric shield layer, thereby preventing malfunction of the stacked chip, electro-static damage, and the like. The through electrode 34 and the through electrodes 4 and 34 connected thereto serve as body contacts for electrically short-circuiting P-type body portions of the semiconductor layers. The body contacts electrically short-circuit the P-type body portions (common potion of separated semiconductor layers) of pMOS transistors, in which N-type semiconductor wells are formed, through wiring layers (not shown) and are grounded. Instead of the layer 32 composed of a porous material, a P+ semiconductor layer doped at a high concentrated or a metal layer can be provided.

### Fifth Embodiment

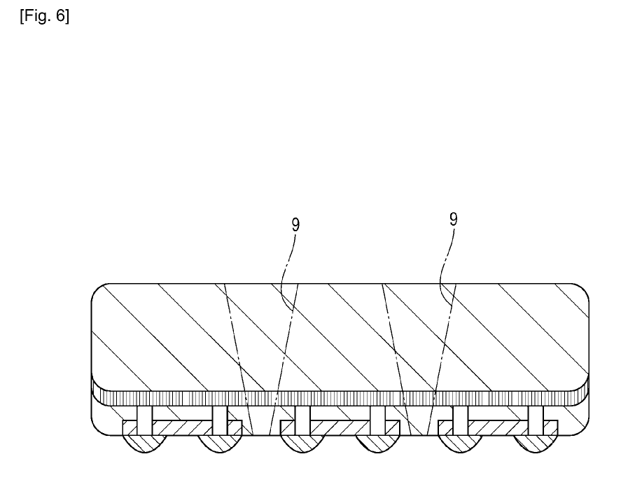

FIG. 6 shows a second semiconductor substrate according to this embodiment. In the embodiment, like in the first embodiment, a separation layer, a semiconductor layer, integrated circuits, through electrodes, and bonding pads are formed. This embodiment is different from the first embodiment in the dicing angle. In this embodiment, grooves 9 are formed with a dicing blade from the back side of a semiconductor substrate 1 on which integrated circuits are not formed, and end surfaces of dies are obliquely cut to separate into integrated circuit chips. Dicing with the dicing blade at different angles produces a structure shown in FIG. 6. As a result, a plurality of dies having inclined end surfaces 112, which are dies corresponding to the chip size of second integrated circuits 7, can be produced. The dies can be produced by dicing the second semiconductor substrate so that the chip size increases toward the bonded surface side.

The subsequent steps for manufacturing a semiconductor device are the same as in the first embodiment or the like. The direction of the dicing end surfaces of the dies is different from in the first embodiment. In this case, however, pores of a porous material constituting the separation layer open in the dicing end surfaces of the separation layer, and thus at least a portion of the separation layer can be removed by penetrating an etching solution into the separation layer.

### Sixth Embodiment

Integrated circuits (CPU) having the function as a central processing unit are formed on a first semiconductor substrate. Integrated circuits (DRAM) having the function as a storage device are formed on a second semiconductor substrate to be arranged at the highest or medium density on another wafer so that the number of the chips obtained is maximized. Further, other storage devices (SRAM) are formed on a third semiconductor substrate to be arranged so that the number of the chips obtained is maximized. Further, other storage devices (FLASH MEMORY) are formed on a fourth semiconductor substrate to be arranged so that the number of the chips obtained is maximized. Each of the storage devices can be formed in a circuit chip size smaller than that of the processing units formed on the first semiconductor substrate.

In addition, a plurality of porous silicon layers having two types of porosity are formed on each of the second to fourth semiconductor substrates by anodization. Further, a silicon single-crystal layer without pores is formed on the porous silicon layers by epitaxial growing. The storage circuit elements are produced and integrated in the epitaxial layer. These small storage circuit chips are cut out from the silicon wafer with a dicer. In this case, the chips are cut so that at least one of the four sides of each chip is inclined, and disposed and bonded to the surfaces of the first operating unit chips through an adhesive layer using a flip bonder, followed by pressure bonding to connect the electrodes. The adhesive layer is formed by applying a solution of an organic insulating material by spin coating and removing a volatile solvent by heat treatment at low temperature.

At this time, initial tackiness is slightly exhibited on the surface of the organic insulating layer by the action of hydrolizable groups (alkoxy groups, silanol groups, or the like). In this state, the individual separated chips are disposed so that the circuit surfaces face downward, pressure-bonded, and heated to transfer the organic insulating layer to a solid phase and strongly bond the chips. In the first semiconductor substrate having the initial shape, the porous silicon layer of 1 millimeter or less is selectively etched out in a planar direction using a mixed solution of hydrofluoric acid and hydrogen peroxide solution through the pore openings of the porous silicon exposed in the side surfaces of the cut chips having inclined sections. The interface between the two porous silicon layers is positioned in the resulting recess, and intrinsic strain energy is accumulated in the interface. When the recess is exposed to a fluid, a fluid wedge is introduced from the recess to start separation from the interface between the two porous silicon layers, thereby separating and removing the substrate portion over the entire chip within a short time. The separated surfaces are coated with the porous silicon layers to inhibit propagation of mechanical damage or cracks due to the water stream.

The porous layers on the surfaces are removed by selective etching and subjected to passivation, and then the first semiconductor substrate is diced to complete high-density, high-speed semiconductor circuit chips in each of which a plurality of memories and logic are three-dimensionally integrated.

### Seventh Embodiment

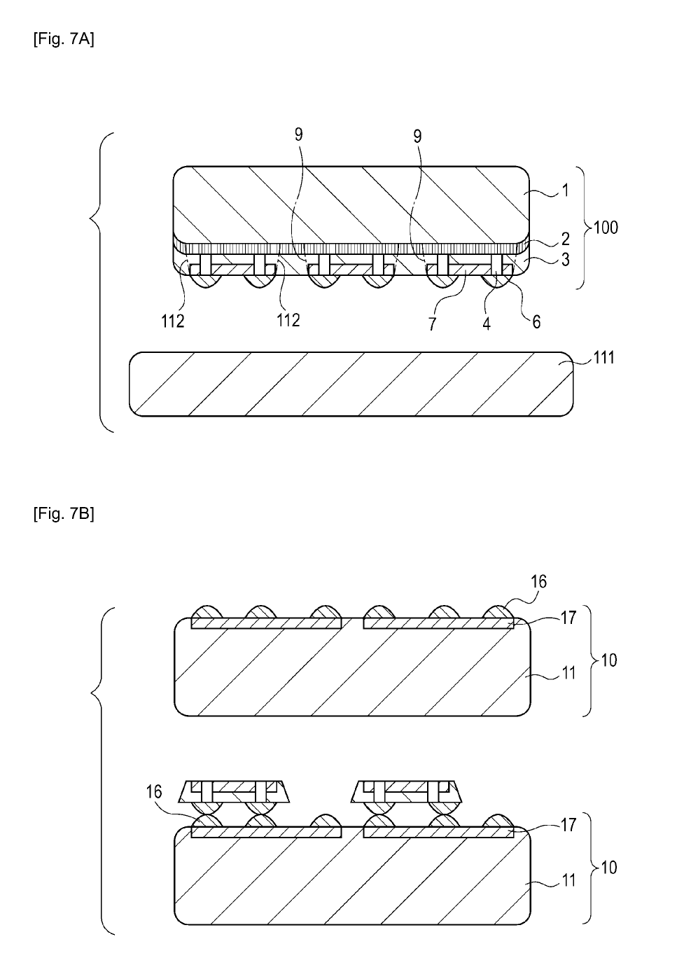

Next, a separation method and a subsequent bonding step according to this embodiment are described with reference to FIGS. 7A and 7B. This embodiment uses a support substrate 111.

A substrate 11 used as a first semiconductor substrate is described later. A separation layer 2 and a semiconductor layer 3 to be transferred are formed on a surface of a second semiconductor substrate 1. As the semiconductor layer 3, a single crystal semiconductor can be used, and, according to demand, like in the first semiconductor substrate, second integrated circuits 7 and bonding pads 6 are formed in the semiconductor layer 3.

The separation step is performed by forming grooves in the semiconductor substrate 1 so that at least one side surface (end surface) of each island region serving as a die is inclined, the semiconductor substrate 1 having the semiconductor layer 3 in which the second integrated circuits 7 are formed. Specifically, a dicing blade is placed at an angle of about 45 degrees to 80 degrees with respect to the surface of the substrate to be cut, and the semiconductor layer 3 is cut by grinding from the surface side thereof. The inclination may decrease or increase toward the bonding side or dicing may be performed at the same inclination (the same direction). When dicing is performed at the same inclination, an useless area can be minimized.

The support substrate 111 is a substrate to which the semiconductor layer 3 is subsequently and temporarily transferred and may include a silicon wafer, glass, a resin film, a metal film, or the like.

The substrate 11 is a semiconductor substrate to which the semiconductor layer 3 is subsequently and permanently transferred and may include a silicon wafer, glass, a resin film, a metal film, or the like. A first semiconductor substrate is prepared as the substrate 11, and first integrated circuits 17 are formed on the surface side of the semiconductor substrate 11 by a known semiconductor manufacturing process. In this case, functional elements such as MOS transistors are formed, an insulating layer is formed and etched, and then a wiring pattern is formed by deposition and CMP of a metal layer for wiring. Then, bonding pads 16 for achieving electric connection with the outside are formed on the uppermost surface. As a result, the first integrated circuits 17 are formed. Then, as shown in FIG. 7A, the island-like regions of integrated circuit chips each having inclined end surfaces (diced end surfaces) 112 are bonded to the surface of the support substrate 111 so that the semiconductor layer 3 faces inward. In this case, according to demand, the surface side of the semiconductor layer 3 can be bonded to the surface side of the substrate 111 through an adhesive. In the separation step, grooves are formed in the semiconductor substrate having the semiconductor layer 3 so that the chip size decreases to the bonded surface side. The grooves may be formed so as to incline the dicing end surfaces including at least a portion of the semiconductor substrate, the separation layer, and the semiconductor layer.

Then, in order to separate the bonded structure at the separation layer 2, a force is applied to the semiconductor substrate 1 in a direction in which a separation function occurs. Consequently, cracks occur in the separation layer 2, and the semiconductor substrate 1 is separated leaving the semiconductor layer 3 having the integrated circuits formed therein on the support substrate 111 side.

When a layer composed of a porous material such as silicon or the like is used as the separation layer 2, pores formed by anodization have openings in the inclined surfaces, and thus an etching solution penetrates into the porous material through the openings to progress selective etching. Therefore, the porous material constituting the separation layer 2 is partially removed to form recesses in the inclined end surfaces 112 of the chips. Thus, when a pressurized fluid is applied, cracks occur in the porous layer along the porous layer due to the wedge function of the fluid to separate the semiconductor substrate 1 from the semiconductor layer 3. In this case, it is effective to use a chip supporting plate by bonding a panel for preventing scattering of the chip or pressing a panel having a recess conforming to the chip shape. A mesh-like chip supporting plate can be used for avoiding inhibition of a water flow.

In addition, when the separation layer includes a plurality of porous layers having different pore densities, separation occurs at the boundaries between the different pore densities by applying a pressurized fluid. The porous layers having different porosities remain on the back of the separated semiconductor chip and the surface of the substrate, and the remaining porous layers serve as protecting layers so that progress and propagation of cracks in elements and circuits can be inhibited during separation with the fluid.

The porous material such as silicon can be formed by anodization in which a current is passed through the entire wafer surface in a chemical conversion solution in a direction perpendicular to the surface. In the anodization, a P⁺-type or N⁺-type substrate can be used or a substrate can be doped with P-type or N-type impurities so that at least an anodization region is P⁺-type or N⁺-type. In the present invention, in particular, a P⁺-type substrate can be used or a substrate can be doped with P-type impurities so that at least an anodization region is P⁺-type. In addition, conductivity is increased by controlling the P⁺-type or N⁺-type region resistivity, and, according to demand, the porous layer is partially left so that when a chip is formed, the porous layer can function as a shield for noise such as electromagnetic waves and the like. The pores are continued from the surface to the end, and the formation direction coincides with the current-carrying direction. That is, the pores of the porous layer grow in a direction perpendicular to the wafer surface, significant enhancement of the etching rate is observed in the growth direction of pores. The inventors found that when a HF solution is used, the increased etching rate reaches several hundreds of thousands of times that of crystal silicon without pores.

However, pore walls are present in the direction perpendicular to the pores, i.e., the direction to the wafer end surfaces, and etching little proceeds because the pore walls are composed of crystal silicon. Namely, the significant anisotropy of the etching rate plays a very important role when the end surfaces of the separation layer are inclined to expose the ends of some of the pores of the porous layer in the inclined surfaces. In order to introduce a fluid into boundaries between a plurality of porous layers, it was found to be most effective to form introduction spaces for applying trigger while avoiding separation at an interface bonded to the adhesive layer. Therefore, selective etching of the inclined surface of the porous layer is effective in forming spaces for initially introducing the fluid.

Alternatively, the substrate 1 may be separated from the semiconductor layer 3 by selectively etching the porous separation layer in the inclined surfaces 112 in the transverse direction without using the fluid.

A method for manufacturing a semiconductor device according to this embodiment is described in detail below with reference to FIGS. 7A and 7B.

As the first semiconductor substrate 11, a semiconductor substrate such as a bulk silicon wafer, an epitaxial silicon wafer, or the like is prepared. Then, as shown by reference numeral 10 in FIG. 7A, a plurality of first integrated circuits 17 is formed on the surface side of the semiconductor substrate 11 by a known manufacturing process. Here, the first integrated circuits are integrated circuit portions which subsequently function as chips (dies). For example, the first integrated circuits are logical IC such as CPU, DSP, or the like.

On the other hand, as shown by reference numeral 100 in FIG. 7A, a separation layer 2 of porous silicon or the like is formed on a second semiconductor substrate 1 such as a bulk silicon wafer, and a plurality of second integrated circuits 7, e.g., at least three second integrated circuits 7, are formed on the separation layer 2 to prepare a wafer as a second semiconductor substrate. Here, the second integrated circuits may be semi-conductor memories such as DRAM, flash memories, or the like. In case of semiconductor memory, the second integrated circuit includes many memory cells, a selection circuit for selecting one of the memory cells, a signal processing circuit for reading and writing signals from and in the memory cells, and the like.

In addition, active elements such as MOS transistors and multilayer wiring for connecting many MOS transistors are formed, and then through holes (including grooves) referred to as “though holes” or “via holes” are formed in a semiconductor layer. Then, insulating films are formed on the inner wall surfaces of the through holes to form insulating inner wall surfaces, and the through holes are filled with a conductor to form through electrodes 4 (through silicon via technique). In this step, the etching time is controlled so that the depth Dt of through holes is smaller than the thickness t3 of the semiconductor layer 3. Namely, the through holes are formed to be such shallow holes that Dt<t3, i.e., the bottoms of the conductive layers in the through holes do not reach the separation layer 2. The thickness t3 of the semiconductor layer 3 can be selected from a range of 1.0 micrometer to 20 micrometers, more preferably a range of 1.0 micrometer to 10 micrometers. For example, when a CMOS circuit is formed, the thickness t3 of the semiconductor layer 3 is 1.0 micrometer to 2.0 micrometers, while when a memory structure is formed, the thickness t3 of the semiconductor layer 3 is 1.0 micrometer to 10.0 micrometers depending on the capacity which stores various memory charges. The depth Dt of the holes or grooves is a half or more of the thickness of the semiconductor layer 3 so that a remaining portion having a thickness of one twentieth or less of the thickness of the semiconductor layer 3 remains at the bottom of a groove. Namely, the through holes are designed to satisfy Expression (1). The conductor may be composed of any one of tin (Sn), nickel (Ni), copper (Cu), gold (Au), and aluminum (Al) or an alloy of at least one of these metals.

Then, bonding pads composed of solder or gold are formed. As a result, a structure 100 shown in FIG. 7A is produced. In the drawing, for the sake of easy understanding, the through electrodes and the bonding pads are shown inside an integrated circuit chip. However, generally, a plurality of through electrodes and bonding pads are provided in the peripheral portion of an integrated circuit chip. In the present invention, the through electrodes are connected to wiring of the integrated circuit of each chip and have the function to achieve electric connection with wiring when chips are stacked. Specifically, a power supply line, an input/output line, a clock signal line, and a ground line can be formed.

Then, dicing is carried out by forming grooves 9 between the adjacent integrated circuits 7 using a dicing saw to separate between island-like regions of the second integrated circuits. At this time, dicing is carried out with a dicing blade which is inclined from the surface side of the semiconductor layer 3, i.e., the surface of the semiconductor substrate. As a result, a plurality of dies each corresponding to the chip size of the second integrated circuits and having the inclined end surfaces 112 can be formed. In addition, the end surfaces of the separation layer 2 may be curved surfaces.

On the other hand, an adhesive is applied to the surface of the support substrate 111, and the support substrate 111 is opposed to the bonding pad 6 side of the island-like semiconductor layer 3. Then, the semiconductor layer 3 and the support substrate 111 are bonded together with the adhesive provided therebetween.

As the adhesive which can be used in the present invention, an adhesive which satisfies low viscosity, low impurities, high weather resistance, low outgassing, low shrinkability, heat resistance at 160 degrees Celsius, high adhesive force, low thermal expansion coefficient, high thermal conductivity, and high volume resistivity can be selected. Examples of the adhesive satisfying these conditions include acrylic, methacrylic (acrylate), epoxy (acid anhydride curing agent), and polyimide, polyimideamide (polyimide=nylon modified) adhesives. The adhesive is applied to the bonded surface (substrate or chip surface), dried leaving predetermined tackiness, and then heat-treated at a predetermined temperature with a predetermined load applied. Instead of or in addition to the adhesive, bonding can be performed using a film (hot-melt sheet) functioning an adhesive. In the present invention, for example, die bonding film FH series, DF series, or HS series, or under fill film UF series, or the like, which is manufactured by Hitachi Chemical Co., Ltd., can be used.

In addition, as a material functioning as both a bonding adhesive and conduction, an anisotropic conductive film or paste may be used for electrically short-circuiting in the thickness direction and insulating between the adjacent bonding pads in the transverse direction.

Then, the exposed portions of the separation layer are partially removed from the side surfaces of the structures formed by bonding the two semiconductor substrates 1 and 111, specifically the inclined side surfaces 112 of an island-like region including the first semiconductor substrate, the separation layer, and the semiconductor layer.

Then, an etching solution or a stream at high pressure not containing abrasive grains is sprayed. Then, the semiconductor layer 3 is separated from the second semiconductor substrate 1 at the separation layer 2. As a result, the semiconductor substrate 1 is removed, and the semiconductor layer 3 having the integrated circuit 7 formed therein is transferred to the support substrate 111 from the semiconductor substrate 1.

The separation method is not limited to the above-described so-called water jet method and may be a gas jet method of spraying high-pressure gas such as nitrogen or the like. In other words, a fluid having a freely deformable wedge function may be sprayed. Alternatively, the separation may be mechanically performed by inserting a wedge including a solid such as a metal between the two semiconductor substrate surfaces. As shown in the drawing, the end surfaces of the die are inclined, and thus when a porous silicon material is used as the separation layer, etching selectively proceeds because many openings are present in the exposed side surfaces of the separation layer. A recess is formed between the semiconductor layer and the support substrate. Therefore, when a wedge is inserted into the recess to apply force vector in a direction in which the two semiconductor substrates are separated from each other, the both substrates are separated at the separation layer 2 having low mechanical strength. Of course, separation of the bonded structure may be started with a solid wedge, and then the bonded structure may be completely separated with a fluid wedge.

After separation, the separation layer 2 remains on the semiconductor substrate 1 side, the semiconductor layer 3 side transferred to the support substrate 111, or the both substrate sides. In particular, when a laminate of at least two porous layers having different porosities is used as the separation layer, cracks are formed in a porous layer having relatively higher porosity near the interface of the porous layers, and separation occurs along the interface. Consequently, the remaining porous layer has a uniform thickness over the entire surface region of the semiconductor substrate having the integrated circuit formed thereon.

Examples of the etching solution include a mixed solution containing hydrogen fluoride and hydrogen peroxide and a mixed solution containing hydrogen fluoride, ammonium fluoride, and hydrogen peroxide. A method of separating only by etching without using the wedge function of the fluid can be used. In this case, the separation layer composed of a porous material may little remain on the exposed surface of the transferred semiconductor layer 3.

When the separation layer 2 remains, according to demand, the remaining separation layer is removed by etching with the mixed solution or the like to expose the back side of the semiconductor layer. Then, the back side of the semiconductor layer is etched until the through electrodes are exposed, and bonding pads are formed using solder, gold, or the like after the through electrodes are exposed.

Then, the semiconductor layer 3 is further moved from the support substrate 111 to a structure 10. As a result, as shown in FIG. 7B, a stacked chip having the integrated circuits 7 and 17 of two different sizes, large and small, is produced. In this method, the semiconductor layer 3 transferred to the support substrate 111 is further transferred to the structure 10. Therefore, the back side of a small chip is bonded to the surface side of a large chip, and the bonding pads on both sides are also bonded together. In addition, as shown in the drawing, the same structure is also formed in an adjacent region on the semiconductor substrate 11. When the number of the integrated circuits stacked is two, dicing is performed by forming grooves in the regions between the adjacent integrated circuits and cutting the bonded structures with a dicing saw disposed vertically, thereby separating the integrated circuits into independent chips.

As a result, a stacked chip having at least the first integrated circuit 7 of small size and the second integrated circuit 17 of large size, i.e., a three-dimensionally mounted semiconductor device, can be produced.

### Eighth Embodiment

In this embodiment, a second semiconductor substrate 1 is used as a common substrate, and chip regions each including a separation layer 2 and a semiconductor layer 3 formed thereon are formed on the substrate 1, the chip regions each having inclined end surfaces 112. Then, the exposed portions of the separation layer 2 exposed in the inclined end surfaces 112 are partially removed, and then separation is performed by spraying a fluid from through grooves 19 formed in a support substrate.

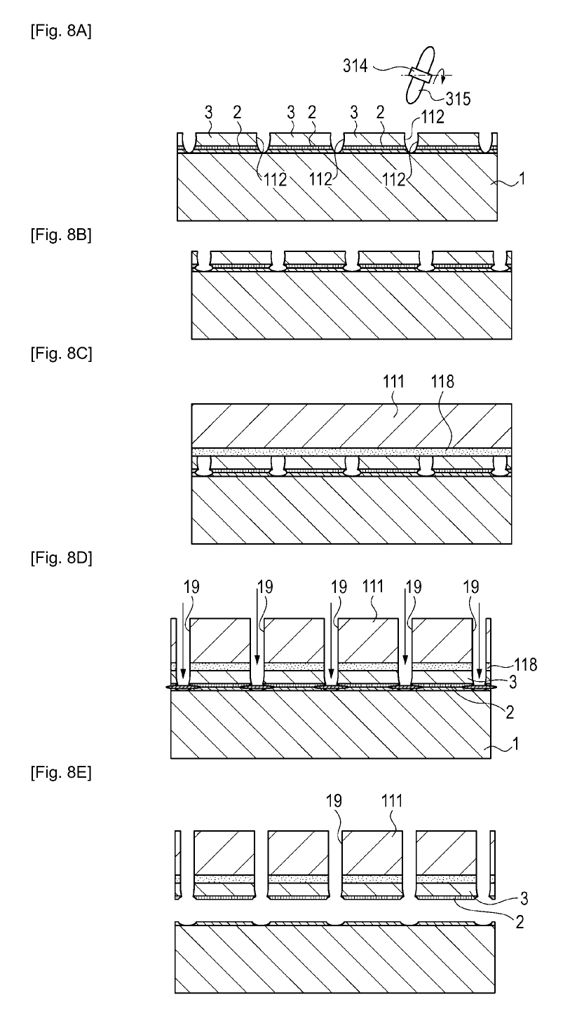

As shown in FIG. 8A, after the separation layer 2 and the semiconductor layer 3 are formed, grooves are formed by a dicing blade 315 inclined to the right direction as shown in the drawing by a variable angle spindle 314, and then grooves are formed by the dicing blade 315 inclined to the left direction as shown in the drawing. As a result, separation groves having the inclined surfaces 112 are formed. In this case, the end surfaces formed by the separation grooves may be curved surfaces.

Consequently, the semiconductor layer 3 and the separation layer 2 are separated for each island-like region. As shown in FIG. 8B, an etching solution is introduced through the separation grooves to partially remove the exposed portions of the separation layer exposed in the inclined surfaces 112. Etching proceeds in the lateral direction because the separation layer is selectively etched. As shown in FIG. 8C, a support substrate 111 is bonded to the surface of the semiconductor layer 3 through a double-faced adhesive sheet 118 which can be separated by heat energy or light energy. As shown in FIG. 8D, the through grooves 19 are formed in the support substrate 111, and a pressurized fluid is applied to the exposed portions of the separation layer through the grooves 19. As shown in FIG. 8E, a bonded structure is separated at the separation layer 2 by the wedge function of the fluid. As a result, the semiconductor layer first formed on the surface of the semiconductor substrate 1 is transferred to the support substrate 111 side.

Then, the support substrate 111 is diced using the separation grooves 19 formed therein. The separation layer 2 remaining on the semiconductor layer 3 after separation can be removed by etching or the like before or after dicing of the support substrate 111 according to demand.

Since the support substrate 111 having the diced semiconductor layer 3 includes the adhesive sheet 118 which can be separated by energy irradiation of ultraviolet light or the like, the semiconductor layer 3 transferred to the support substrate 111 can be further transferred to another substrate (refer to ninth embodiment). As a modified example of the eighth embodiment, integrated circuits of larger size than the integrated circuits formed in the semiconductor layer 3 of the second semiconductor substrate 1 may be formed on the support substrate 111, and bonding pads of the integrated circuits may be bonded together.

### Ninth Embodiment

First, the same structure as shown in FIG. 8E of the above-described eighth embodiment is further transferred to a semiconductor substrate 11 on which integrated circuits are formed as shown by reference numeral 10 in FIG. 7B.

Then, the diced stacked chip is die-bonded to a mounting substrate composed of a metal, ceramic, an insulating sheet having metal wiring, or the like, and then packaged.

Although any one of the drawings is enlarged in the longitudinal direction, in fact, the chip size (the lateral length in the drawings) is significantly larger than the thickness (the length in the longitudinal direction).

In the above-described embodiments, the integrated circuits 7 and 17 formed on the first semiconductor substrate 11 and each semiconductor layer 3 may be the same or different circuits. The integrated circuits 17 may be circuits on a relatively large circuit scale. As the integrated circuits 7, semiconductor memory requiring a storage operation, such as DRAM and the like, and nonvolatile semiconductor memory referred to as “flash memory”, such as EEPROM, MRAM, and the like, can be used. The number of the layers stacked is not limited to 2 as shown in the drawing, and may be 8 or more, particularly 12 or more. On the other hand, as the integrated circuits 17, the above-described logical IC on the larger circuit scale than the integrated circuits 7 or 27 can be used. Further, the semiconductor substrate 11 may include a thin layer.

### Tenth Embodiment

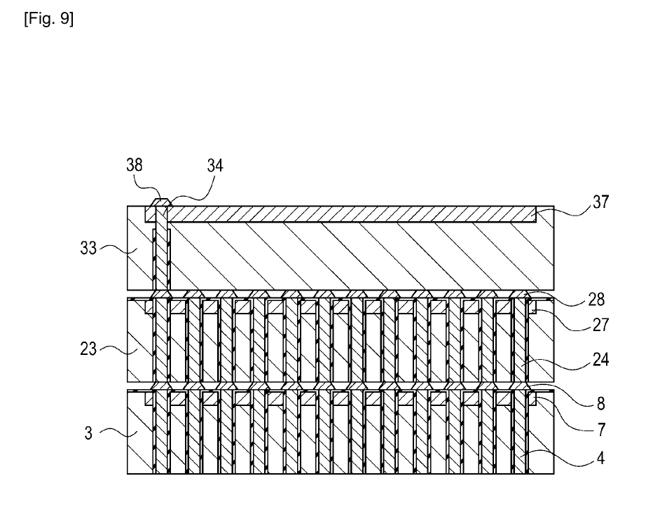

FIG. 9 in a enlarged partial view of a stacked chip obtained by the method for manufacturing a semiconductor device according to the present invention. In this embodiment, the above-described semiconductor layer 3 in which integrated circuits are formed is transferred three times or more to produce a stacked chip.

FIG. 9 shows a cross-section of a portion in which three integrated circuits of small chip size are stacked. FIG. 9 does not show an integrated circuit chip of large chip size provided below the three integrated circuits. The stacked chip of this embodiment includes the integrated circuit chip of large chip size and the structure stacked thereon as shown in FIG. 9.

In the semiconductor layer 3 in which integrated circuits 7 of small chip size, such as semiconductor memory or the like, through electrodes 4 and solder bumps 8 serving as bonding pads are formed. Further, a semiconductor layer 23 in which an integrated circuit 27 composed of the same semiconductor memory is formed is stacked on the semiconductor layer 3, through electrodes 24 and solder bumps 28 serving as bonding pads being formed in the semiconductor layer 23.

Further, a semiconductor layer 33 in which an integrated circuit 37 composed of the same semiconductor memory is formed is stacked on the semiconductor layer 23. A through electrode 34 is disposed so as to be stacked on the lower through electrodes 24 and 4 and short-circuited to provide conduction therebetween. In each of the semiconductor layers 3, 23, and 33, insulating films are formed on the inner walls of through holes, and thus each of the semiconductor layers is not short-circuited with the insides of the through holes. On the other hand, the remaining separation layer 32 composed of a porous material is a low-resistance layer composed of silicon containing a high concentration of boron, and thus the separation layer 32 is short-circuited with the through electrode 34 so that the low-resistance layer 32 used as the separation layer composed of a porous material can be used as an electric shield layer, thereby preventing malfunction of the stacked chip, electro-static damage, and the like. The through electrode 34 and the through electrodes 4 and 34 connected thereto serve as body contacts for electrically short-circuiting P-type body portions of the semiconductor layers. The body contacts electrically short-circuit the P-type body portions (common potion of separated semiconductor layers) of pMOS transistors, in which N-type semiconductor wells are formed, through wiring layers (not shown) and are grounded. Instead of the layer 32 composed of a porous material, a P+ semiconductor layer doped at a high concentration or a metal layer can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-092315, filed Apr. 6, 2009, and Japanese Patent Application No. 2009-092316, filed Apr. 6, 2009, which are hereby incorporated by reference herein in their entirety.

1. A method for manufacturing a semiconductor device, comprising the steps of:
forming a plurality of first integrated circuits on the surface side of a first semiconductor substrate;
forming a plurality of second integrated circuits in a semiconductor layer which is formed on a separation layer provided on a second semiconductor substrate, the chip size of the second integrated circuits being smaller than that of the first integrated circuits;
separating at least the semiconductor layer for each second integrated circuit so that the end surfaces of the separation layer are inclined or curved surfaces;
bonding the first semiconductor substrate and the second semiconductor substrate so that bonding pads formed on the surface sides of the first integrated circuits are bonded to bonding pads formed on the surface sides of the second integrated circuits to form a bonded structure;
separating the bonded structure along the separation layer to obtain the first semiconductor substrate to which the semiconductor layer having the second integrated circuits formed therein is transferred; and
dicing the first semiconductor substrate to which the plurality of second integrated circuits are transferred to obtain stacked chips each including the first integrated circuit and the second integrated circuit.

2. The method for manufacturing a semiconductor device according to claim 14, wherein the separating step includes a step of dicing the second semiconductor substrate so that dicing end surfaces each including the second semiconductor substrate, the separation layer, and the semiconductor layer are inclined or curved.

3. The method for manufacturing a semiconductor device according to claim 2, wherein at least a portion of the separation layer in the dicing end surfaces is removed, and then a pressurized fluid is applied to separate the semiconductor layer.

4. The method for manufacturing a semiconductor device according to claim 2, wherein at least a portion of the separation layer in the dicing end surfaces is removed by etching to separate the semiconductor layer.

5. The method for manufacturing a semiconductor device according to claim 3, wherein the separation layer includes a plurality of porous silicon layers having different porosities so that separation occurs at an interface between the layer with different porosities by applying the fluid.

6. The method for manufacturing a semiconductor device according to claim 3, wherein the second semiconductor substrate is removed from a plurality of the separated semiconductor layers bonded to the first semiconductor substrate by spraying the fluid while moving an opening, which ejects the fluid, relatively to the first semiconductor substrate.

7. The method for manufacturing a semiconductor device according to claim 1, wherein the second integrated circuits have through electrodes connected to the bonding pads.

8. A semiconductor device comprising:
a plurality of first integrated circuits provided on a semiconductor substrate;
a second integrated circuit bonded to the first integrated circuits through bonding pads, the chip size of the second integrated circuit being smaller than that of the first integrated circuits; and
a semiconductor layer in which the second integrated circuit is provided, the semiconductor layer having inclined end surfaces.

9. A method for manufacturing a semiconductor device, comprising the steps of:
preparing a semiconductor substrate having a semiconductor layer formed on a separation layer;
separating at least the semiconductor layer for each region so that the end surfaces of the separation layer are inclined or curved surfaces;
bonding a plurality of the separated semiconductor layers to a support substrate to form a bonded structure; and
removing at least a portion of the separation layer exposed in the inclined or curved surfaces and separating the bonded structure along the separation layer to form the support substrate to which the semiconductor layer is transferred.

10. The method for manufacturing a semiconductor device according to claim 9, wherein at least a portion of the separation layer in the end surfaces is removed, and then a pressurized fluid is applied to separate the semiconductor layer from the semiconductor substrate.

11. The method for manufacturing a semiconductor device according to claim 10, wherein the semiconductor layer is separated from the semiconductor substrate by applying an etching solution or a pressurized fluid through a through groove which passes through the support substrate.

12. The method for manufacturing a semiconductor device according to claim 9, further comprising a step of further transferring, to another substrate, the semiconductor layer transferred to the support substrate.

13. The method for manufacturing a semiconductor device according to claim 9, wherein an integrated circuit is formed in the semiconductor layer, the integrated circuit having a bonding pad and a through electrode connected to the bonding pad.
